(19) United States
(12) Patent Application Publication
(10) Pub. No.: US 2023/0098773 A1
(43) Pub. Date: Mar. 30, 2023

(54) IMMERSION-TYPE POROUS HEAT DISSIPATION SUBSTRATE STRUCTURE

(71) Applicant: AMULAIRE THERMAL TECHNOLOGY, INC., New Taipei City (TW)

(72) Inventors: CHENG-SHU PENG, New Taipei City (TW); TZE-YANG YEH, New Taipei City (TW); CHIH-HUNG SHIH, Hsinchu County (TW)

(21) Appl. No.: 17/489,942

(22) Filed: Sep. 30, 2021

(51) Int. Cl. F28F 13/00; F28D 15/02

(52) U.S. Cl. CPC F28F 13/003; F28D 15/02; F28F 2255/18

(57) ABSTRACT

An immersion-type porous heat dissipation substrate structure is provided. The immersion-type porous heat dissipation substrate structure includes a porous heat dissipation base formed by sintering of metal powder. The porous heat dissipation base is immersed in a two-phase coolant for increasing an amount of bubbles that is generated, and has a porosity that is controlled to be between 5% and 50%. Or, the porous heat dissipation base has more than one porosity.

### FIELD OF THE DISCLOSURE

The present disclosure relates to a heat dissipation substrate structure, and more particularly to an immersion-type porous heat dissipation substrate structure.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type porous heat dissipation substrate structure.

In one aspect, the present disclosure provides an immersion-type porous heat dissipation substrate structure. The immersion-type porous heat dissipation substrate structure includes a porous heat dissipation base formed by sintering of metal powder. The porous heat dissipation base is immersed in a two-phase coolant for increasing an amount of bubbles that is generated, and has a porosity that is controlled to be between 5% and 50%.

In an exemplary embodiment, the metal powder is selected from one of copper, aluminum, silver, and gold, or any combination thereof

In another aspect, the present disclosure provides an immersion-type porous heat dissipation substrate structure. The immersion-type porous heat dissipation substrate structure includes a porous heat dissipation base formed by sintering of metal powder. The porous heat dissipation base is immersed in a two-phase coolant for increasing an amount of bubbles that is generated, and has more than one porosity.

In an exemplary embodiment, the metal powder is selected from one of copper, aluminum, silver, and gold, or any combination thereof

In an exemplary embodiment, the porous heat dissipation base includes a surface layer and an inner layer that is located below the surface layer. The surface layer has a first porosity, the inner layer has a second porosity, and the first porosity is greater than the second porosity.

In an exemplary embodiment, the surface layer is in contact with the two-phase coolant, and the inner layer is not in contact with the two-phase coolant.

In an exemplary embodiment, the porous heat dissipation base includes a base and a fin structure that is formed on the base. The fin structure includes a plurality of fins that are arranged at intervals and are connected to a surface of the base. The base has a first porosity, the fin structure has a second porosity, and the second porosity is greater than the first porosity.

In an exemplary embodiment, the porous heat dissipation base includes a center structure and an outer peripheral structure that is formed along a periphery of the center structure. The center structure has a first porosity, the outer peripheral structure has a second porosity, and the second porosity is greater than the first porosity.

Therefore, one of the beneficial effects of the present disclosure is that, in the immersion-type porous heat dissipation substrate structure provided by the present disclosure, by virtue of “the porous heat dissipation base being formed by sintering of the metal powder and being immersed in the two-phase coolant” and “the porous heat dissipation base having the porosity that is controlled to be between 5% and 50%, or the porous heat dissipation base having more than one porosity”, not only can an amount of bubbles that is generated be increased, but a high mechanical strength and an enhanced heat dissipation effect can also be achieved at the same time.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an immersion-type porous heat dissipation substrate structure according to a first embodiment of the present disclosure;

FIG. 2 is a schematic side view of the immersion-type porous heat dissipation substrate structure according to a second embodiment of the present disclosure;

FIG. 3 is a schematic side view of the immersion-type porous heat dissipation substrate structure according to a third embodiment of the present disclosure; and

FIG. 4 is a schematic perspective view of the immersion-type porous heat dissipation substrate structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

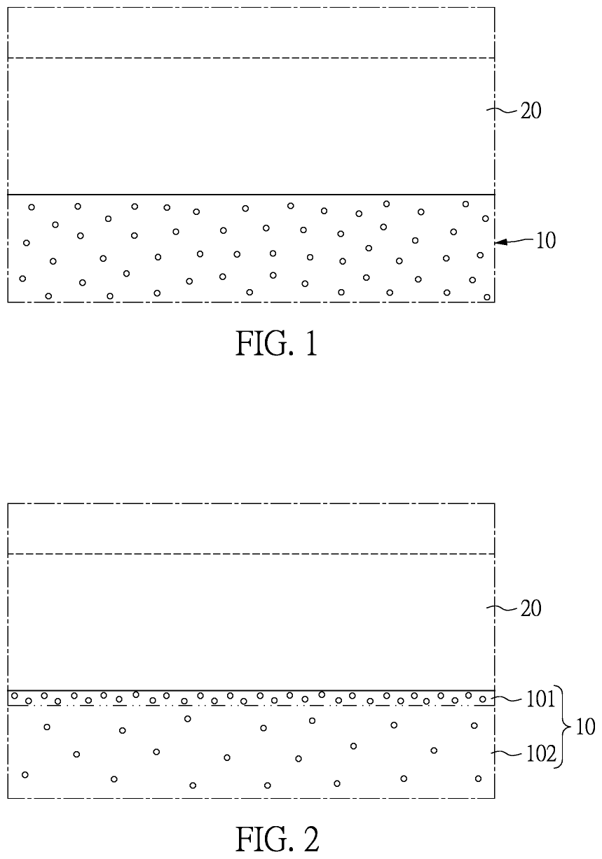

Referring to FIG. 1, one embodiment of the present disclosure provides an immersion-type porous heat dissipation substrate structure, which can be used for contacting a heat producing element. As shown in FIG. 1, the immersion-type porous heat dissipation substrate structure of the present embodiment includes a porous heat dissipation base 10. The porous heat dissipation base 10 is formed by sintering of metal powder, and can be completely immersed in a two-phase coolant 20 (e.g., FLUORINERT™). Therefore, in the present embodiment, through forming an immersion-type heat dissipation substrate structure having a porous structure by sintering of metal powder and through immersion in a two-phase coolant, a quantity of bubbles formed through an endothermic gasification process of the two-phase coolant can be significantly increased, thereby greatly enhancing a heat dissipation effect.

In the present embodiment, the metal powder is selected from one of copper, aluminum, silver, and gold, or any combination thereof In addition, it is worth mentioning that a porosity of the porous heat dissipation base 10 of the present embodiment is controlled to be between 5% and 50%. In this way, both a high mechanical strength and an enhanced heat dissipation effect can be achieved in the porous heat dissipation base 10 of the present embodiment.

Furthermore, it should be noted that the porous structure is shown in FIG. 1 in an exaggerated or enlarged manner to facilitate a better understanding of the present disclosure.

### Second Embodiment

Referring to FIG. 2, one embodiment of the present disclosure provides an immersion-type porous heat dissipation substrate structure, which can be used for contacting a heat producing element. As shown in FIG. 2, the immersion- type porous heat dissipation substrate structure of the present embodiment includes a porous heat dissipation base 10. The porous heat dissipation base 10 is formed by sintering of metal powder, and can be partially immersed in a two-phase coolant 20. Further, the porous heat dissipation base 10 of the present embodiment has more than one porosity.

More specifically, in the present embodiment, the porous heat dissipation base 10 includes a surface layer 101 and an inner layer 102 that is located below the surface layer 101. The surface layer 101 has a first porosity, the inner layer 102 has a second porosity, and the first porosity (e.g., being between 50% and 95%) is greater than the second porosity (e.g., being lower than 50%). In this way, a mechanical strength of the inner layer 102 is greater than that of the surface layer 101. That is, a mechanical strength of a primary structure is configured to be greater than that of a non-primary structure.

Furthermore, in the present embodiment, the surface layer 101 is in contact with the two-phase coolant 20, and the inner layer 102 is not in contact with the two-phase coolant 20, so that the porous heat dissipation base 10 of the present embodiment is partially immersed in the two-phase coolant 20. Accordingly, a heat dissipation effect can be enhanced by increasing an amount of the bubbles that is generated in the surface layer 101 of the porous heat dissipation base 10.

In addition, it should be noted that the porous structure is shown in FIG. 2 in an exaggerated or enlarged manner to facilitate a better understanding of the present disclosure.

### Third Embodiment

Referring to FIG. 3, one embodiment of the present disclosure provides an immersion-type porous heat dissipation substrate structure, which can be used for contacting a heat producing element. As shown in FIG. 3, the immersion-type porous heat dissipation substrate structure of the present embodiment includes a porous heat dissipation base 10. The porous heat dissipation base 10 is formed by sintering of metal powder, and can be completely immersed in a two-phase coolant 20. Further, the porous heat dissipation base 10 of the present embodiment has more than one porosity.

More specifically, in the present embodiment, the porous heat dissipation base 10 includes a base 103 and a fin structure 104 that is formed on the base 103. In addition, the fin structure 104 includes a plurality of fins 1041 that are arranged at intervals and are connected to a surface of the base 103. The base 103 has a first porosity, the fin structure 104 has a second porosity, and the second porosity (e.g., being between 50% and 95%) is greater than the first porosity (e.g., being lower than 50%). In this way, a mechanical strength of the base 103 is greater than that of the fin structure 104. That is, the mechanical strength of the primary structure is configured to be greater than that of the non-primary structure. Therefore, the porous heat dissipation base 10 of the present embodiment is configured to enhance a heat dissipation effect through the fin structure 104, and the heat dissipation effect can be further enhanced by increasing the amount of the bubbles that is generated through the fin structure 104, so that both a high mechanical strength and an enhanced heat dissipation effect can be achieved in the porous heat dissipation base 10 of the present embodiment.

In addition, it should be noted that the porous structure is shown in FIG. 3 in an exaggerated or enlarged manner to facilitate a better understanding of the present disclosure.

### Fourth Embodiment

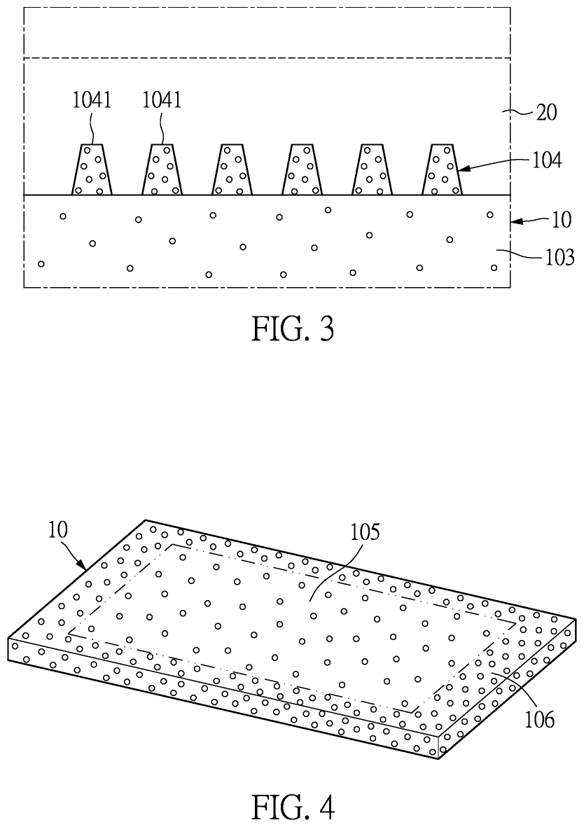

Referring to FIG. 4, one embodiment of the present disclosure provides an immersion-type porous heat dissipation substrate structure, which can be used for contacting a heat producing element. As shown in FIG. 4, the immersion-type porous heat dissipation substrate structure of the present embodiment includes a porous heat dissipation base 10. The porous heat dissipation base 10 is formed by sintering of metal powder, and can be completely immersed in a two-phase coolant 20. Further, the porous heat dissipation base 10 of the present embodiment has more than one porosity.

More specifically, in the present embodiment, the porous heat dissipation base 10 includes a center structure 105 and an outer peripheral structure 106 that is formed along a periphery of the center structure 105. The center structure 105 has a first porosity, the outer peripheral structure 106 has a second porosity, and the second porosity (e.g., being between 50% and 95%) is greater than the first porosity (e.g., being lower than 50%). In this way, a mechanical strength of the center structure 105 of the porous heat dissipation base 10 is greater than that of the outer peripheral structure 106. That is, the mechanical strength of the primary structure is configured to be greater than that of the non-primary structure. Therefore, the porous heat dissipation base 10 of the present embodiment is configured to enhance a heat dissipation effect through the outer peripheral structure 106, and the heat dissipation effect can be further enhanced by increasing the amount of the bubbles that is generated through the outer peripheral structure 106, so that both a high mechanical strength and an enhanced heat dissipation effect can be achieved in the porous heat dissipation base 10 of the present embodiment.

In addition, it should be noted that the porous structure is shown in FIG. 4 in an exaggerated or enlarged manner to facilitate a better understanding of the present disclosure.

### Beneficial Effects of the Embodiments

In conclusion, in the immersion-type porous heat dissipation substrate structure provided by the present disclosure, by virtue of “the porous heat dissipation base 10 being formed by sintering of the metal powder and being immersed in the two-phase coolant 20” and “the porous heat dissipation base 10 having the porosity that is controlled to be between 5% and 50%, or the porous heat dissipation base 10 having more than one porosity”, not only can an amount of bubbles that is generated be increased, but a high mechanical strength and an enhanced heat dissipation effect can also be achieved at the same time.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

1-2. (canceled)

3. An immersion-type porous heat dissipation substrate structure, comprising:
a porous heat dissipation base formed by sintering of metal powder, wherein the porous heat dissipation base is immersed in a two-phase coolant for contacting a heat producing element that is immersed in the two-phase coolant, wherein the porous heat dissipation base includes a surface layer and an inner layer that is located below the surface layer, the surface layer has a first porosity, the inner layer has a second porosity, and the first porosity is greater than the second porosity such that an amount of bubbles generated through the surface layer is greater than an amount of bubbles generated through the inner layer, and a mechanical strength of the inner layer is greater than a mechanical strength of the surface layer.

4. The immersion-type porous heat dissipation substrate structure according to claim 3, wherein the metal powder is selected from one of copper, aluminum, silver, and gold, or any combination thereof.

5-6. (canceled)

7. The immersion-type porous heat dissipation substrate structure according to claim 3, wherein the porous heat dissipation base includes a fin structure, the fin structure includes a plurality of fins that are arranged at intervals and are connected to the surface layer.

8. (canceled)
